(19) United States
(12) Patent Application Publication
(10) Pub. No.: US 2026/0334164 A1
(43) Pub. Date: Oct. 22, 2026

(54) PLASMA PROCESSING METHOD AND METHOD FOR INSPECTING PATTERN OF METAL FILM

(71) Applicant: Hitachi High-Tech Corporation, Minato-ku, Tokyo (JP)

(72) Inventors: Miyako MATSUI, Tokyo (JP); Kenichi KUWAHARA, Tokyo (JP); Tomoyasu SHOHJOH, Tokyo (JP); Miki AOYAGI, Tokyo (JP)

(21) Appl. No.: 19/103,426

(22) PCT Filed: Nov. 2, 2023
(86) PCT No.: PCT/JP2023/039691

§ 371 Date: Feb. 12, 2025

(51) Int. Cl. H10P 74/20; H10P 50/00; H10P 50/26

(52) U.S. Cl. CPC H10P 74/203; H10P 50/267; H10P 50/71

(57) ABSTRACT

A plasma processing method according to an embodiment of the invention for forming a pattern of a metal film includes: a first step (S1) of acquiring, using an image of a mask pattern acquired using an electron beam, information on roughness and a dimension of the mask pattern and on a grain of the metal film; a third step (S2) of defining an etching condition for the metal film based on an allowable value for the roughness of the pattern of the metal film; and a fourth step (S3 to S7) of etching the metal film using the defined etching condition for the metal film.

### TECHNICAL FIELD

The present invention relates to a plasma processing method and a method for inspecting a pattern of a metal film.

### BACKGROUND ART

Due to miniaturization and three-dimensionalization of a functional element product such as a semiconductor element, a three-dimensional processing technique for various materials is important in a dry etching step during semiconductor production, and a technique of processing a complex shape by controlling a shape at an atomic layer level is required. Miniaturization also advances in an interconnection step, and in a Cu (copper) interconnection which has been generally used in the related art, an increase in interconnection resistance in the future due to a decrease in an interconnection width becomes a problem. This is because, although a barrier metal layer is formed between an interlayer film material and the Cu interconnection in order to prevent electromigration in which metal atoms in the interconnection move due to a current to cause disconnection, when the interconnection width decreases, a ratio of the barrier metal layer in the interconnection width rapidly increases, and the increase in the interconnection resistance accelerates.

In order to solve this problem, it has been studied to use molybdenum (Mo), ruthenium (Ru), or the like as an interconnection material. Since these metal materials have a relatively high melting point and can thin the barrier metal, resistance of an interconnection including a barrier metal is expected to be reduced. Since such metal materials can also form an interconnection pattern by plasma etching or the like, the interconnection pattern can be formed from a metal film with relatively large grains, and therefore, the metal materials are expected as materials with which a low-resistance interconnection can be obtained.

As shown in NPL 1, a resistance value of a metal interconnection can be calculated not only by a resistance value of a metal material but also by a sum of a resistance value due to electron scattering at a sidewall of an interconnection pattern and a resistance value due to electron scattering at a grain boundary. Therefore, in order to obtain a low-resistance interconnection, a processing technique for reducing roughness and surface alteration of a surface and a sidewall of an interconnection pattern is important.

Meanwhile, in a technique in the related art for measuring or inspecting roughness, a dimension, and the like of an interconnection pattern in a non-destructive manner, for example, information on a dimension of a pattern sample can be obtained by scanning and emitting an electron beam to the pattern sample, detecting secondary electrons secondarily generated from a sample surface, and acquiring a secondary electron image with a scanning electron microscope. For example, a dimension 111 and roughness 112 of a mask pattern 103 at an uppermost layer of a sample can be measured by scanning and emitting an incident electron beam 116 to a pattern sample as shown in (FIG. 3A to detect secondary electrons 117 generated at a sample surface and acquire a secondary electron image as shown in FIG. 3B.

However, in the related art, since an electron beam of several hundred eV or more and several keV or less is generally used as the incident electron beam 116, as shown in FIG. 3A, when a width of a pattern (interconnection pattern) of an etching target material 102 under the mask pattern 103 is the same as the dimension 111 of the mask pattern 103 or narrower than the dimension 111, the incident electron beam 116 cannot reach the pattern of the etching target material 102, and a dimension, roughness, and a grain thereof cannot be measured. Even when a thickness of the mask pattern 103 at the uppermost layer of the sample is thin and the incident electron beam 116 reaches the pattern (interconnection pattern) of the etching target material 102, the secondary electrons 117 generated from a sidewall thereof are blocked by the mask pattern 103 and cannot be detected by a detector, and thus the dimension, the roughness, and the grain of the pattern of the etching target material 102 cannot be measured.

Transmission electron microscopy is known as a method for evaluating a dimension, roughness, and a grain of an interconnection pattern that is not located at a pattern uppermost layer. Using the transmission electron microscopy, it is possible to measure the dimension, the roughness, and the grain of the pattern of the etching target material 102 based on an image obtained by emitting electrons having energy of about several hundred keV and detecting an electron beam passing through the sample. However, in this method, in order to detect electrons transmitted through the sample, it is necessary to thin the sample and inspect in a destructive manner. Accordingly, a wafer evaluated using this method cannot be subjected to the following step in a semiconductor production line.

As shown in FIG. 4A, as a method for measuring an internal structure of a sample without cutting the sample, a technique in the related art disclosed in PTL 1 has a function of emitting, to a sample, an incident electron beam 118 having energy enough to reach a portion not exposed to the incident electron beam 118 and detecting a signal 119 secondarily generated from a portion to which the incident electron beam 118 is emitted. Using this technique, the incident electron beam 118 having energy enough to reach the etching target material 102 under the mask pattern 103 is emitted thereto, the reflected electrons 119 secondarily generated from the pattern of the etching target material 102 are detected, and thus information on roughness 114, a dimension 113, and a grain 115 of the pattern of the etching target material 102 can be obtained by acquiring a reflected electron image as shown in FIG. 4B.

### CITATION LIST

### Patent Literature

PTL 1: JPH7-27549A
PTL 2: JP2006-215020A
PTL 3: JP2019-215788A

### Non Patent Literature

NPL 1: R. S. Smith and 12 other authors, “An evaluation of Fuchs-Sondheimer and Mayadas-Shatzkes models below 14 nm node wide lines”, [online], Feb. 13, 2019, AIP Advances 9, 025015 (2019), [accessed Oct. 11, 2023], Internet <URL: https://doi.org/10.1063/1.5063896>
NPL 2: Sara. Paolillo and 5 other authors, “Direct metal etch of ruthenium for advanced interconnect”, Journal of Vacuum Science and Technology B 36, 03E103 (2018)
NPL 3: Shibesh Dutta and 8 other authors, “Thickness dependence of the resistivity of platinum-group metal thin films”, Journal of Applied Physics 122, 025107 (2017)
NPL 4: A. F. Mayadas and 1 other author, “Electrical-Resistivity Model for Polycrystalline Films: the Case of Arbitrary Reflection at External Surfaces”, Physical Review B 1, 1382-Published 15 Feb. 1970
NPL 5: Daniel Gall, “The search for the most conductive metal for narrow interconnect lines”, Journal of Applied Physics 127, 050901 (2020)

### SUMMARY OF INVENTION

### Technical Problem

First, NPL 2 discloses a technique of forming an interconnection pattern by dry etching an interconnection material such as Mo and Ru. In the interconnection pattern, since interconnection resistance increases when roughness is formed at a surface or a sidewall, in order to form a low-resistance interconnection pattern, a processing technique of controlling and processing a cross section of an interconnection to have a desired shape and simultaneously reducing the formation of the roughness at the surface or the roughness at the sidewall is necessary. When the interconnection pattern is processed by dry etching, since a mask pattern is transferred to the interconnection material at a lower layer, it is a problem to reduce mask roughness. The roughness of the interconnection pattern after processing also varies depending on a processing condition for the interconnection pattern. Further, there is a problem that the roughness formed after processing the interconnection pattern of Ru varies depending on not only a Ru etching condition but also on a film formation method and a film formation temperature of Ru.

As shown in NPL 2 and NPL 3, in a metal interconnection, since electrons are easily scattered at a grain boundary, interconnection resistance depends on a grain size, and when a grain is small, there is a problem that the interconnection resistance increases. Further, when an interconnection pattern is processed by plasma etching or the like, a grain boundary in a metal material is more easily etched than the inside of a grain, and thus there is a problem that roughness at a sidewall of the interconnection pattern increases as etching progresses from the grain boundary. In this way, there is a problem that roughness of the interconnection pattern is formed depending on not only mask roughness but also on a grain size of an etching target material. Further, there is a problem that the interconnection resistance increases or disconnection occurs due to such roughness, electrical characteristics of the interconnection deteriorate, and desired device characteristics cannot be obtained.

Meanwhile, with regard to a dimension and roughness of a mask pattern before the interconnection pattern is processed as described above, a scanning electron microscope scans and emits the incident electron beam 116 having the energy of several hundred eV or more and several keV or less to the mask pattern 103, the secondary electrons 117 generated from the surface of the sample are detected to acquire the image, and thus the information on the sample such as the dimension 111 and the roughness 112 of the mask pattern 103 can be obtained. However, in this method, when the width of the interconnection pattern under the mask pattern 103 is equal to or narrower than the dimension (width) 111 of the mask pattern 103, the secondary electrons generated from the sidewall of the interconnection pattern are blocked by the mask pattern 103 and cannot be detected by the detector, and thus there is a problem that the dimension 113, the roughness 114, and the grain 115 of the interconnection pattern cannot be measured inline.

As the method for measuring the internal structure of the sample without cutting the sample, the technique in the related art disclosed in PTL 1 has the function of emitting the incident electron beam 118 having the energy enough to reach the portion not exposed to the incident electron beam 118 and detecting the signal including a large number of the reflected electrons 119 secondarily generated from the portion to which the incident electron beam 118 is emitted. When the etching target material (metal film) 102 before etching under the mask pattern 103 as shown in (a) in FIG. 2 is evaluated using this technique, an image of a signal secondarily generated from the etching target material (metal film) 102 can be acquired, and information on the grain 115 of the metal interconnection can be evaluated.

However, using this method, the information on the dimension 111 and the roughness 112 of the mask pattern 103 and the information on the grain 115 of the metal film 102 below can be obtained, but electrical characteristics of the interconnection pattern formed after etching cannot be evaluated. In addition, when an interconnection pattern as shown in FIG. 4B is evaluated, the information on the dimension 113 and the roughness 114 of the pattern (interconnection pattern) of the etching target material 102 and the information on the grain 115 can be obtained, but the electrical characteristics of the formed interconnection pattern cannot be evaluated. Therefore, it is not possible to process the etching target material 102 to have the appropriate dimension 113 and the appropriate roughness 114, and to manage a pattern shape and electrical characteristics according to comprehensive information on the roughness 112 and the dimension 111 of the mask pattern 103 and on the grain 115 of the etching target material 102.

An object of the invention is to acquire information such as roughness and a grain of a mask or a metal interconnection inline, perform etching such that roughness of an interconnection pattern is equal to or less than an allowable value, and thus perform etching while ensuring interconnection resistance. Further, another object of the invention is to provide an interconnection pattern having low interconnection resistance by estimating an optimum etching condition based on measured information on a dimension, roughness, and a grain.

### Solution to Problem

A plasma processing method according to an embodiment of the invention for forming a pattern of a metal film includes: a first step of acquiring, using an image of a mask pattern acquired using an electron beam, information on roughness and a dimension of the mask pattern and on a grain of the metal film; a third step of defining an etching condition for the metal film based on an allowable value for roughness of the pattern of the metal film; and a fourth step of etching the metal film using the defined etching condition for the metal film.

### Advantageous Effects of Invention

Interconnection resistance can be estimated based on information on a dimension and roughness of a mask pattern and on a grain size of a metal film, and an optimum etching condition can be set based on an allowable value for roughness of a pattern of the metal film based on the acquired information to create an interconnection pattern having low interconnection resistance, thereby providing a device having favorable performance.

### BRIEF DESCRIPTION OF DRAWINGS

FIG. 1 shows an example of a process flow of a plasma processing method in an embodiment.

FIG. 2 shows a sample cross-sectional structure in a flow of the plasma processing method in the embodiment.

FIGS. 3A and 3B show a problem in a method in the related art, in which (a) is a cross-sectional view of a sample where a mask is formed after metal pattern processing, and (b) is a top view of a secondary electron image.

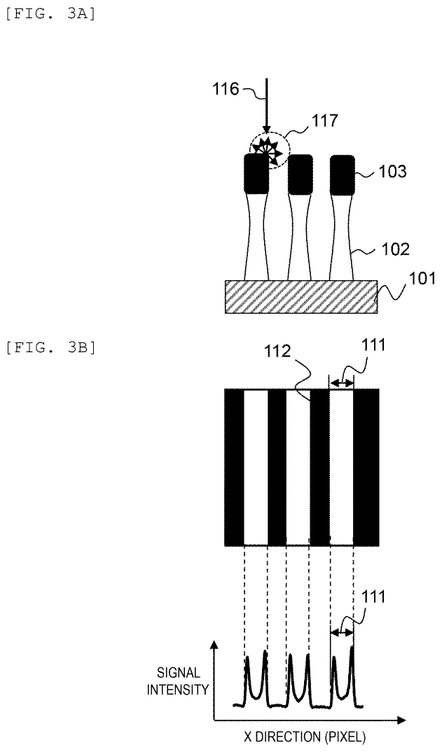

FIGS. 4A and 4B show an example of a method for inspecting a metal pattern in the embodiment, in which (a) is a cross-sectional view when an electron beam that can reach the metal pattern is emitted and (b) is a top view of a reflected electron image.

FIG. 5 shows an example of a scanning secondary electron microscope used in pattern inspection in the embodiment.

FIGS. 6A and 6B show an example of a secondary electron image and a reflected electron image of a mask pattern acquired in step 1 in the embodiment.

FIGS. 7A and 7B show an example of a secondary electron image and a reflected electron image of a pattern acquired in step 8 in the embodiment.

FIG. 8 shows an example of a plasma processing apparatus to which the embodiment is applied.

In FIGS. 9A and 9B, FIG. 9A shows a method for setting an allowable value for roughness in the embodiment, and FIG. 9B shows a method for setting a mask protective film thickness in the embodiment.

FIG. 10 shows a method for setting a sidewall protective film thickness in the embodiment.

### DESCRIPTION OF EMBODIMENTS

Hereinafter, an embodiment of the disclosure will be described in detail with reference to the drawings. In all the drawings, components having the same functions are denoted by the same reference numerals, and repeated description thereof is omitted.

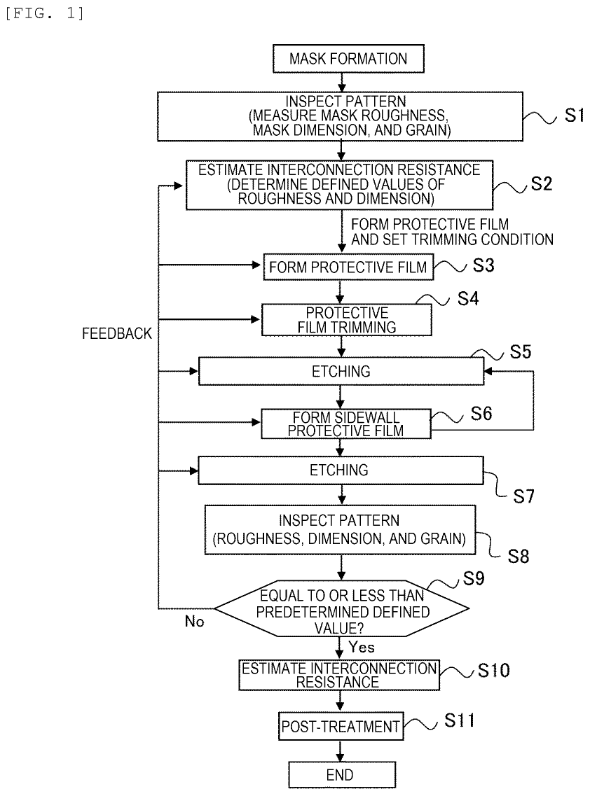

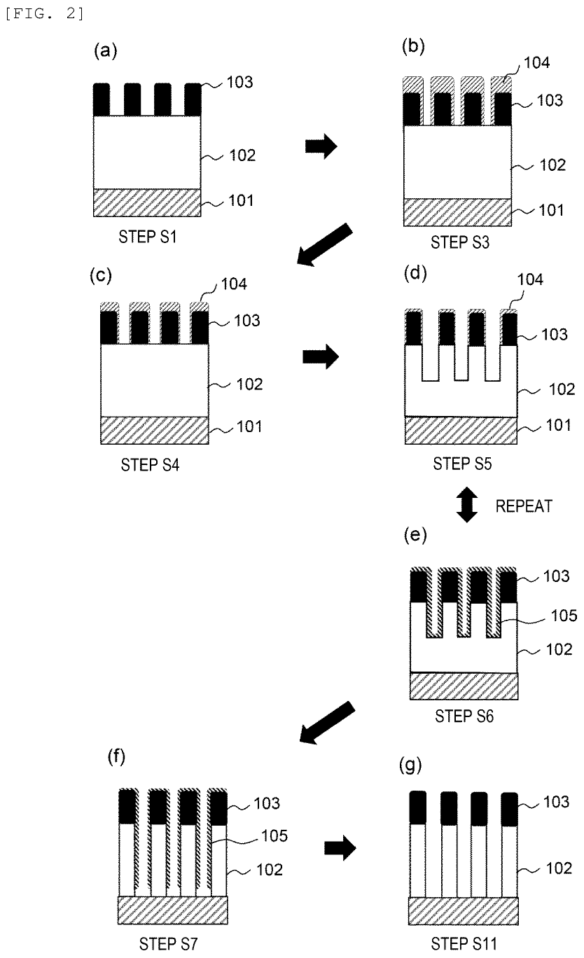

FIG. 1 shows an example of a process flow of a pattern formation method in the embodiment. FIG. 2 is an example of a pattern cross-sectional view showing a process flow of the pattern formation method in the embodiment. In the embodiment, a method for processing an etching target material (metal film) 102 that is a metal material will be described based on the flow in FIG. 1. As the etching target material 102 that is the metal material, for example, a metal film containing Mo or Ru may be used. In FIG. 2, a substrate 101 corresponds to a wafer. In the embodiment, as an example, a case is described in which a silicon nitride film (SiN) is used as a material of a mask pattern 103, and Ru is used as the metal material of the etching target material (metal film) 102. The embodiment can also be implemented in the same way when the material of the mask pattern 103 is a material containing oxygen (O), nitrogen (N), and carbon (C) in addition to Si such as a silicon oxide film (SiO₂), a silicon nitride film (SiN), or silicon carbide (SiC), a material containing titanium (Ti) such as titanium nitride (TiN) and titanium dioxide (TiO₂), a material containing aluminum (Al) or tantalum (Ta) such as aluminum oxide (Al₂O₃) and tantalum nitride (TaN), or a material containing carbon (C).

First, as a step for inspecting a wafer after mask formation (step S1), an incident electron beam is emitted, using a semiconductor inspection apparatus, to a wafer where the mask pattern 103 is formed on the etching target material (metal film) 102 to measure a width dimension of the mask pattern 103, roughness of a mask pattern sidewall, and a grain of the etching target material (metal film) 102 (step S1). After the mask pattern 103 shown in (a) in FIG. 2 is formed, the incident electron beam is scanned and emitted, and electrons secondarily generated are detected to acquire an image. As the incident electron beam, an electron beam having energy that can reach the etching target material (metal film) 102 through the mask pattern 103 is emitted, and a component mainly including the secondarily generated secondary electrons is detected, thereby measuring the roughness and the dimension of the mask pattern 103. Meanwhile, when the incident electron beam reaches the etching target material (metal film) 102, a large number of electrons are reflected by metal atoms and reach a detector. Since a scattering cross-section of reflected electrons increases depending on an atomic number of the target metal atoms, information on the grain of the etching target material (metal film) 102 can be obtained by acquiring an image mainly including the reflected electrons.

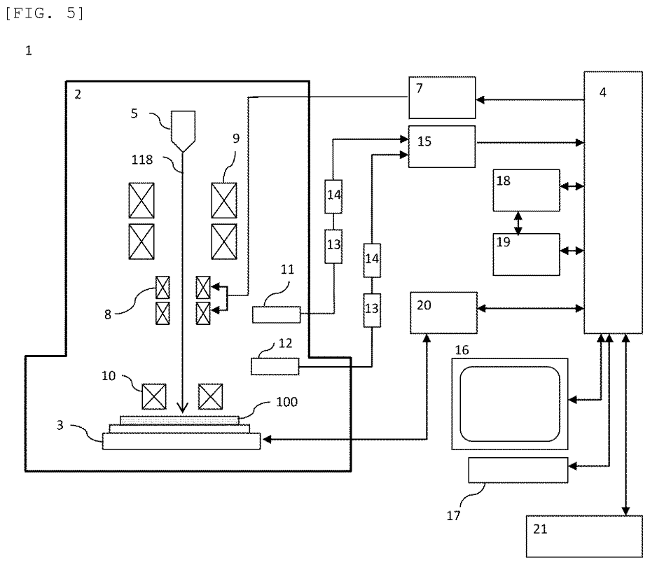

An image of a signal mainly including the reflected electrons can be acquired, for example, using a semiconductor inspection apparatus 1 as shown in FIG. 5. An incident electron beam 118 emitted from an electron source 5 is deflected by a scanning coil 8 controlled by a scanning control unit 7, and is raster-scanned on a wafer 100 placed on a moving stage 3. Secondary electrons and reflected electrons secondarily generated from a surface of the wafer 100 due to scanning of the incident electron beam 118 are detected by a secondary electron detector 11 and a reflected electron detector 12, respectively, and are amplified by an amplifier 13. The secondary electron detector 11 detects a low energy component mainly including the secondary electrons generated from the wafer 100, and the reflected electron detector 12 detects a high energy component mainly including the reflected electrons. An electronic signal amplified by the amplifier 13 is sent to a control unit 4 via a converter 14 and a detector control unit 15, and is displayed as a scanning image on a monitor 16 by the control unit 4.

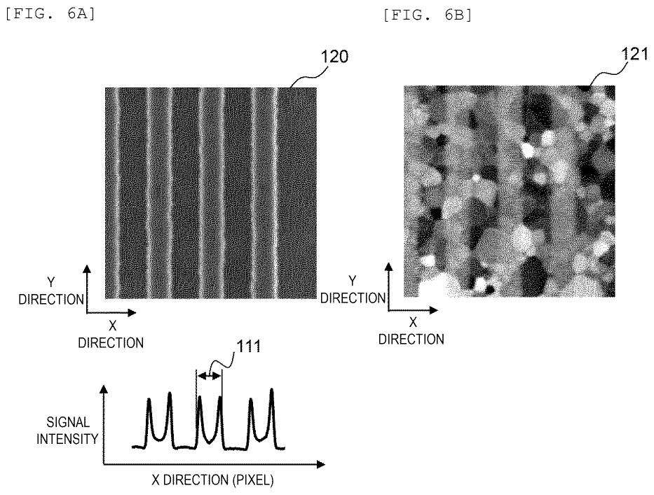

In FIGS. 6A and 6B, as examples of images acquired with the semiconductor inspection apparatus 1 in the step for inspecting the wafer after mask formation (step S1), FIG. 6A shows a secondary electron image 120 in which secondary electrons are mainly acquired, and FIG. 6B shows a reflected electron image 121 in which reflected electrons are mainly acquired. In FIG. 6A, a large number of secondary electrons generated at an edge of the mask pattern 103 are acquired, and the dimension and the roughness of the mask pattern 103 can be measured. In FIG. 6B, shows the reflected electron image 121 generated by the reflected electrons reflected by atoms contained in the etching target material (metal film) 102, and since contrast differs depending on a grain crystal orientation, the grain of the etching target material (metal film) 102 can be evaluated.

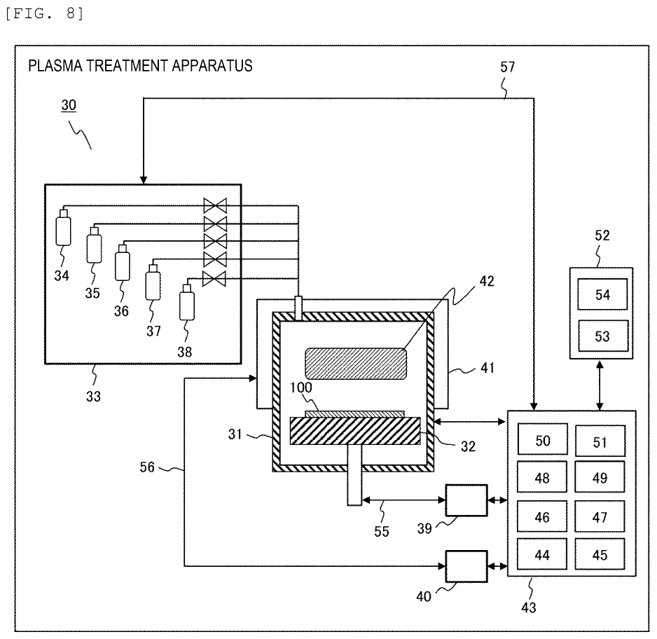

The roughness of the mask pattern 103 can be measured, for example, using a method disclosed in PTL 2, the grain of the etching target material (metal film) 102 can be measured, for example, using a method disclosed in PTL 3, and thus grain information such as a grain size, a length of a grain boundary crossing the mask pattern 103, and a crystal orientation can be obtained. The secondary electron image 120, the reflected electron image 121, and the measured information on the dimension and the roughness of the mask pattern 103 and on the grain of the etching target material (metal film) 102 acquired in step S1 are stored in a storage unit 18. Here, although the storage unit 18 and a calculation unit 19 are shown in the semiconductor inspection apparatus 1 in FIG. 5, the storage unit 18 and the calculation unit 19 may be disposed in an external server 21 or a plasma processing apparatus 30 shown in FIG. 8.

Next, interconnection resistance after processing the etching target material (metal film) 102 is estimated (step S2) on an assumption that a pattern of the etching target material (metal film) 102 is transferred with the same roughness as the mask pattern 103, based on the information on the roughness and the dimension of the mask pattern 103 and on the grain of the etching target material (metal film) 102 obtained in the pattern inspection (step S1) performed after mask formation. The measured information on the dimension and the roughness of the mask pattern 103 and on the grain of the etching target material (metal film) 102 stored in the storage unit 18 is sent to the calculation unit 19 to estimate the interconnection resistance after processing and calculate an allowable value for the roughness.

Here, NPL 4 and NPL 5 disclose that interconnection resistance depends not only on resistivity of an interconnection material but also on scattering of electrons flowing in an interconnection due to roughness of an interconnection sidewall and scattering at a grain boundary of the interconnection material. A relationship among the scattering at the sidewall, the scattering at the grain boundary, and an effective resistance value of the interconnection can be expressed by the following (equation 1).

ρ=ρ_{θ}+ρ_{θ}λ*3(1−p)/4d+ρ_{θ}λ*3R/2D(1−R) . . . (1)

Here, ρ_{θ} is bulk resistivity of an interconnection metal material, λ is a mean free path of an electron in an interconnection metal, D is a grain size coefficient, p is a sidewall scattering coefficient, d is an interconnection width, and R is a grain boundary scattering coefficient. Accordingly, effective bulk resistivity ρ of an interconnection pattern can be obtained by a sum of the scattering due to the sidewall roughness and the scattering due to the grain boundary. Although the etching target material (metal film) 102 is not processed at the stage of step S2, since the etching target material (metal film) 102 is processed basically based on the mask pattern 103 in metal etching in subsequent step S5, here, the dimension and the roughness in the secondary electron image 120 of the mask pattern 103 acquired in step S1 are used as a dimension and sidewall roughness of the etching target material (metal film) 102 to estimate the interconnection resistance. The interconnection width d can be obtained from the dimension of the mask pattern 103 in the secondary electron image 120. The sidewall scattering coefficient p varies depending on the interconnection roughness, and thus can be obtained based on the roughness of the mask pattern 103 measured from the secondary electron image 120. The grain size coefficient D can be obtained from a grain size of the etching target material (metal film) 102 acquired from the reflected electron image 121.

After the calculation unit 19 estimates the interconnection resistance, it is checked whether an estimated resistance value is within a desired resistance value range stored in the storage unit 18. When the interconnection resistance value estimated in step S2 is within the desired resistance value range, the etching target material (metal film) 102 is etched according to an etching condition stored in the storage unit 18 (steps S3, S4, and S5). On the other hand, when the interconnection resistance value estimated in step S2 is not within the desired resistance value range, the etching target material (metal film) 102 is etched under a processing condition stored in a database such that the roughness of the pattern of the etching target material (metal film) 102 is within the allowable value. When the resistance value is not within the desired resistance value range, first, the dimension and the roughness of the pattern of the etching target material (metal film) 102 necessary for making the interconnection resistance within the desired resistance value range are calculated.

As an example, FIG. 9A shows a method for setting the allowable value for the roughness of the pattern of the etching target material (metal film) 102, and shows a relationship between the interconnection resistance and the roughness. For example, as shown in FIG. 9A, when the measured grain size is large, the allowable value for the sidewall roughness required to obtain the desired interconnection resistance can be set to be larger than that when the grain size is small. As a relation between the interconnection resistance and the roughness, a relationship acquired in advance using a test pattern may be used, or a relationship obtained by calculation based on the relationship in (equation 1) may be used.

When the allowable value of the roughness of the pattern of the etching target material (metal film) 102 thus obtained is larger than the roughness of the mask pattern 103 measured in step S1, for example, the roughness can be reduced by forming a protective film 104 in steps S3 and S4. In FIG. 9B, shows a relationship between a thickness of the protective film 104 formed on the mask pattern 103 and the mask roughness. This relationship can be acquired in advance through an experiment using a test pattern and stored in the storage unit 18. When the measured roughness of the mask pattern 103 is larger than the allowable value of the roughness of the pattern of the etching target material (metal film) 102, by forming the protective film 104, the roughness of the mask pattern 103 can be reduced to be equal to or less than the allowable value of the roughness of the pattern of the etching target material (metal film) 102. In this way, the thickness of the protective film 104 on the mask pattern 103 formed in steps S3 and S4 is set according to the measured roughness of the mask pattern 103.

FIG. 8 shows an overall configuration of an example of the plasma processing apparatus 30 used in the invention. The plasma processing apparatus 30 includes a processing chamber 31, a wafer stage 32, a gas supply unit 33, a bias power supply 39, a radio frequency power supply 40, a radio frequency application unit 41, an apparatus control unit 43, and the like. The apparatus control unit 43 includes functional blocks such as a gas control unit 44, an exhaust system control unit 45, a radio frequency control unit 46, a bias control unit 47, a protective film formation step control unit 48, an etching control unit 49, a database 50, and a storage unit 51. A control unit 52 includes a calculation unit 53 and a database storage unit 54, and can determine, by referring to the database storage unit 54, whether the calculation unit 53 ends a desired processing. The calculation unit 53 and the database storage unit 54 of the control unit 52 may be shared with the calculation unit 19 and the storage unit 18 of the semiconductor inspection apparatus 1 shown in FIG. 5.

The plasma processing apparatus 30 is provided with the wafer stage 32 provided in the processing chamber 31 and the gas supply unit 33 including a gas cylinder and a valve. Based on a control signal 57 from the apparatus control unit 43, a protective film formation gas 34, a trimming gas 35, an etching gas 36, a sidewall protective film formation gas 37, and a post-processing gas 38 are supplied to the processing chamber 31 according to a processing step.

A processing gas supplied to the processing chamber 31 is decomposed into plasma 42 in the processing chamber 31 by radio frequency power 56 applied to the radio frequency application unit 41 from the radio frequency power supply 40 controlled by the apparatus control unit 43. Pressure in the processing chamber 31 can be maintained constant by a variable conductance valve (not shown) and a vacuum pump (not shown) connected to the processing chamber 31 in a state in which the processing gas of predetermined flow rate flows therein. Radicals generated by decomposition into the plasma 42 in the processing chamber 31 are diffused in the processing chamber 31 and emitted onto the surface of the wafer 100 placed on the wafer stage 32. Ions generated by the plasma 42 are accelerated by a bias voltage 55 applied to the wafer stage 32 from the bias power supply 39 controlled by the bias control unit 47 and emitted onto the surface of the wafer 100.

Next, as an example of an etching method in this embodiment, an example of a method of performing etching such that the roughness of the mask pattern acquired in step S1 is reduced to fall within the allowable value will be described below. First, as shown in (b) in FIG. 2, the thin protective film 104 is formed on the mask pattern 103 (step S3). For example, as shown in FIG. 9B, the thickness of the protective film 104 to be formed is set based on the relationship between the thickness of the protective film 104 and the roughness of the mask pattern 103.

As an example, a method of improving the mask roughness by forming a C-containing thin film as the protective film 104 on the mask pattern 103 will be described with reference to FIG. 2. In this embodiment, as an example, a case is described in which SiN is used as the material of the mask pattern 103 and Ru is used as the etching target material (metal film) 102. The embodiment can also be implemented in the same way when the material of the mask pattern 103 is a material containing C, O, and N in addition to Si such as SiO₂, Si₃N₄, and SiC, a material containing Ti such as TiN and TiO₂, a material containing Al or Ta such as Al₂O₃ and TaN, or a material containing C.

First, the wafer 100 is introduced onto the wafer stage 32 in the processing chamber 31, and a processing condition in a protective film formation step stored in the database storage unit 54 in the control unit 52 is transmitted to the apparatus control unit 43 based on the roughness measured in step S1 and the allowable value for the roughness determined in step S2 as a condition for processing the mask pattern 103 formed on the wafer 100.

When the protective film formation step (step S3) is started, the protective film formation gas 34 is supplied to the processing chamber 31 at predetermined flow rate based on the control signal 57 from the apparatus control unit 43. The supplied protective film formation gas 34 is converted into the plasma 42 by the radio frequency power 56 applied to the radio frequency application unit 41, and generates radicals and ions. The radicals and ions generated from the protective film formation gas 34 have a property of bonding with or adhering to the material of the mask pattern 103 and depositing thereon, the radicals and ions generated by the plasma 42 reach the surface of wafer 100 and form the C-containing protective film 104 on a top surface and the sidewall of the mask pattern 103. The protective film formation step control unit 48 can control a film thickness and film quality of the protective film 104 by setting and adjusting the flow rate of the protective film formation gas 34, the radio frequency power applied to the radio frequency application unit 41, a substrate temperature, a plasma exposure time, and the like.

As the protective film formation gas 34, for example, a gas containing C such as CH₄, CF₄, CHF₃, CH₃F, C₄F₈, CO₂, or CO, COS gas, or a mixed gas of the above gas and Ar, He, O₂ gas, CO₂ gas, CO gas, COS gas, SO₂ gas, N₂, or H₂ may be used. As the protective film formation gas 34, for example, HBr gas, BCl₃ gas, SO₂ gas, or a mixed gas of the above gas and Ar, He, O₂ gas, CO₂ gas, CO gas, COS gas, SO₂ gas, N₂, and H₂ may be used, and in this case, a thin film obtained by a reaction between the radicals and ions generated by the plasma 42 due to the above gas with the material of the mask pattern 103 is formed as the protective film 104. The film thickness of the protective film 104 can be adjusted by the plasma exposure time, the gas flow rate of the protective film formation gas 34, the substrate temperature, and the like. Alternatively, the film thickness of the protective film 104 can be adjusted by adjusting a degree of plasma dissociation by the radio frequency power 56 applied to the radio frequency application unit 41 to adjust reactivity between the generated radicals and ions and the material surface.

After the protective film 104 is formed in step S3, trimming is performed by removing a part of the protective film (step S4). An example of a cross section of the pattern after the trimming is shown in (c) in FIG. 2. After the protective film 104 is formed, trimming is further performed and a part of the protective film 104 is removed, thus a shape of the protective film 104 is smoothed, the pattern roughness and roughness of a surface of the protective film are reduced, and a desired mask dimension can be obtained at the same time.

Based on a control signal from the protective film formation step control unit 48, the protective film trimming gas 35 is supplied to the processing chamber 31 at predetermined flow rate, and is converted into the plasma 42 by the radio frequency power 56 applied to the radio frequency application unit 41, thereby generating radicals and ions. The radicals and ions generated from the protective film trimming gas 35 react with a material of the protective film 104 or remove a part of the material of the protective film 104 by sputtering, thereby reducing the pattern roughness and the roughness of the surface of the protective film.

When the protective film 104 is made of a material containing a large amount of C, for example, a mixed gas of argon gas (Ar), helium gas (He), O₂ gas, CO₂ gas, CO gas, COS gas, SO₂ gas, nitrogen gas (N₂), and hydrogen gas (H₂), or a gas containing F such as NF₃, CF₄, CHF₃, or SF₆ may be used as the trimming gas 35.

The roughness of the protective film 104 may be adjusted by the plasma exposure time, the gas flow rate of the protective film trimming gas 35, the substrate temperature, and the like. Alternatively, the film thickness, the film quality, and the roughness of the protective film 104 can be adjusted by adjusting the degree of plasma dissociation by the radio frequency power 56 applied to the radio frequency application unit 41 to adjust the reactivity between the generated radicals and ions and the material surface. Alternatively, by adjusting the bias voltage 55 applied to the wafer stage 32 with the bias power supply 39, energy of ions incident on the surface of the wafer 100 can be controlled to adjust the film thickness, the film quality, and the roughness of the protective film 104.

In this embodiment, in order to obtain the pattern having the roughness within the defined range, the trimming (step S4) is performed after the formation of the protective film (step S3), and alternatively, the trimming of the mask pattern 103 may be performed before the formation of the protective film to reduce the roughness and then the protective film 104 may be formed, or either the formation of the protective film or the trimming may be performed. After the trimming (step S4) is performed after the formation of the protective film (step S3), it may be checked whether the protective film having a desired dimension and desired roughness can be actually formed on the mask pattern by performing the same pattern inspection as that in step S1.

When the mask roughness satisfies the defined roughness and a mask pattern having a desired dimension is obtained, the etching target material (metal film) 102 is etched (step S5).

The etching gas 36 is supplied to the processing chamber 31 at predetermined flow rate based on the control signal 57 from the apparatus control unit 43. The supplied etching gas 36 is converted into the plasma 42 by the radio frequency power 56 applied to the radio frequency application unit 41, and generates radicals and ions for etching the etching target material (metal film) 102. The radicals and ions generated by the plasma 42 reach the surface of the wafer 100, and as shown in (d) in FIG. 2, etching of the etching target material (metal film) 102 is started using the mask pattern 103 and the protective film 104 as the mask. As the etching gas 36, for example, a gas containing a halogen gas such as Cl₂, HBr, NF₃, or SF₆, or a mixed gas of the above gas and O₂ gas may be used. As the etching gas 36, a fluorocarbon gas such as CF₄ or CHF₃, or a mixed gas of a hydrofluorocarbon gas and O₂ gas may be used. Ions generated from the etching gas 36 are accelerated by the bias voltage 55 applied to the wafer stage 32 from the bias power supply 39 controlled by the bias control unit 47 and emitted onto the surface of the wafer 100.

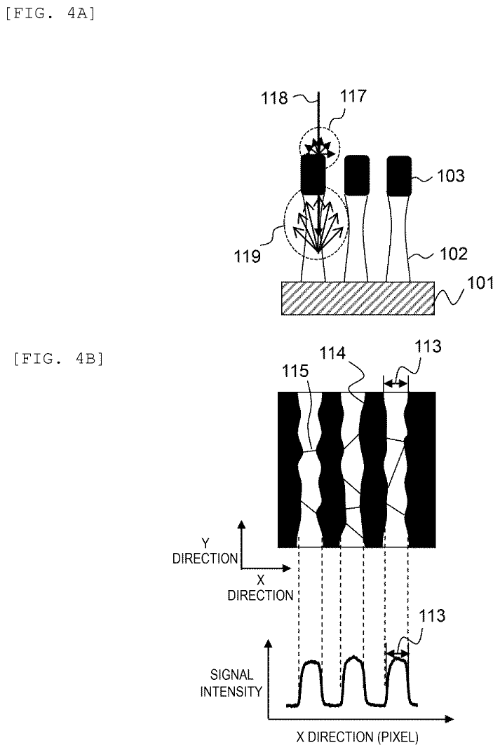

Here, in the etching in step S5, the etching of the etching target material (metal film) 102 in a sidewall direction proceeds, and a desired metal pattern shape may not be obtained or the roughness may increase. In particular, as shown in (b) in FIGS. 4A and 4B, when there are a large number of grain boundaries of the etching target material (metal film) 102 at a pattern sidewall portion, since the etching proceeds more easily at the boundaries than inside grains, the roughness may increase. In such a case, for example, as shown in (e) in FIG. 2, by forming a sidewall protective film 105 on the sidewall of the pattern of the etching target material (metal film) 102, the increase in the roughness can be prevented.

Examples of a method for forming the sidewall protective film 105 during the etching of the etching target material (metal film) 102 include a method of adding a gas having a sidewall protection effect to the etching gas of the etching target material (metal film) 102 described in step S5 and performing etching, and a method of performing a step of forming the sidewall protective film 105 (step S6) after the step of etching a layer to be etched (step S5) and performing steps S5 and S6 in a cycle.

As the method of adding the gas having the sidewall protection effect to the etching gas of the etching target material (metal film) 102, for example, there is a method of forming a C-based protective film on the sidewall using a gas having high deposition properties such as CH₄ gas and hydrofluorocarbon in a mixed gas of Cl₂ gas and O₂ gas. Alternatively, HBr gas, CO₂ gas, COS gas, N₂ gas, SO₂ gas, or the like may be added to react with the sidewall of the etching target material (metal film) 102 and form a low-volatility reaction film, thereby preventing the sidewall from being etched.

When the step of forming the sidewall protective film 105 (step S6) is performed, the sidewall protective film formation gas 37 is supplied to the processing chamber 31 at predetermined flow rate based on the control signal from the protective film formation step control unit 48, and is converted into the plasma 42 by the radio frequency power 56 applied to the radio frequency application unit 41 to generate radicals and ions. The radicals and ions generated from the sidewall protective film formation gas 37 have a property of bonding with or adhering to the etching target material (metal film) 102 and depositing thereon, and the radicals and ions generated by the plasma 42 reach the surface of the wafer 100 and form the sidewall protective film 105 at the upper surface and the sidewall of the mask pattern 103 and the sidewall (sidewall surface) of the pattern of the etching target material (metal film) 102. The protective film formation step control unit 48 can control a film thickness and film quality of the sidewall protective film 105 by setting and adjusting the flow rate of the sidewall protective film formation gas 37, the radio frequency power 56 applied to the radio frequency application unit 41, the substrate temperature, the plasma exposure time, and the like.

As the sidewall protective film formation gas 37, for example, a gas containing C such as CH₄, CF₄, CHF₃, CH₃F, C₄F₈, CO₂, or CO, HBr gas, BCl₃ gas, COS gas, SO₂ gas, or a mixed gas of the above gas and Ar, He, O₂ gas, CO₂ gas, CO gas, COS gas, SO₂ gas, N₂, or H₂ may be used. A thin film obtained by a reaction between the radicals or ions generated by the plasma 42 due to the above gas and the material of the etching target material (metal film) 102 is formed as the sidewall protective film 105 on the sidewall of the etching target material (metal film) 102. The film thickness of the sidewall protective film 105 can be adjusted by the plasma exposure time, the gas flow rate of the sidewall protective film formation gas 37, the substrate temperature, and the like. Alternatively, the film thickness of the sidewall protective film 105 can be adjusted by adjusting the degree of plasma dissociation by the radio frequency power 56 applied to the radio frequency application unit 41 to adjust reactivity between the generated radicals and ions and the material surface.

After formation of the sidewall protective film 105, plasma generated by further introducing a gas such as Ar gas, He gas, N₂ gas, or H₂ gas may be emitted to a groove pattern to smooth a shape of the sidewall protective film 105 and reduce roughness of the groove pattern or roughness of a surface of the sidewall protective film.

When the etching (step S7) of the etching target material (metal film) 102 is completed, pattern inspection is performed (step S8). As an example, a case where the pattern after the etching shown in (f) in FIG. 2 is inspected using the semiconductor inspection apparatus 1 will be described. After the pattern of the etching target material (metal film) 102 is formed, an electron beam having energy that can reach the pattern of the etching target material (metal film) 102 through the mask pattern 103 is emitted to the wafer 100 as an incident electron beam. Secondary electrons and reflected electrons generated from the surface of the wafer 100 due to scanning of the electron beam are detected by the secondary electron detector 11 and the reflected electron detector 12, and are amplified by the amplifier 13. An electronic signal amplified by the amplifier 13 is displayed as a scanning image on the monitor 16 by the control unit 4.

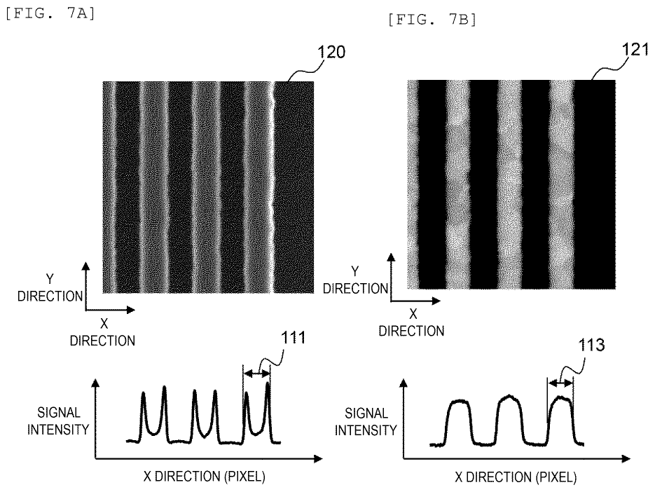

FIGS. 7A and 7B show an example of a method for inspecting the wafer after a pattern to be etched is formed. The secondary electron detector 11 can detect a component mainly including the secondary electrons, acquire the secondary electron image 120 as shown in FIG. 7A, and measure the dimension and the roughness of the mask pattern. Meanwhile, the reflected electron detector 12 detects a component mainly including the reflected electrons, acquires the reflected electron image 121 as shown in FIG. 7B, and measures the width dimension and the sidewall roughness of the pattern of the etching target material (metal film) 102, as well as grain information of the metal pattern such as a grain size, a length of a grain boundary crossing the interconnection pattern, and a crystal orientation. When the pattern of the etching target material (metal film) 102 is particularly fine, if it is difficult to evaluate the grain after etching the etching target material (metal film) 102, a grain boundary can be accurately obtained by matching the pattern with a grain image before the pattern processing of the etching target material (metal film) 102 measured in step S1. The secondary electron image 120, the reflected electron image 121, the measured information on the dimension and the roughness of the pattern of the etching target material (metal film) 102 and on the grain, and the dimension and the roughness of the mask pattern 103 acquired in step S8 are stored in the storage unit 18.

Thereafter, it is determined whether the roughness of the pattern of the etching target material (metal film) 102 after processing is equal to or less than the predetermined allowable value (step S9). When the roughness is not within the range of the predetermined allowable value, the mask pattern 103 is corrected by a defined value. When the roughness after the pattern formation of the etching target material (metal film) 102 increases as compared with a value of the roughness of the mask pattern 103 measured in step S1 and stored in the storage unit 18, feedback can be performed on conditions for the protective film formation step (step S3), the trimming (step S4), the etching (steps S5 and S7), and the sidewall protective film formation (step S6).

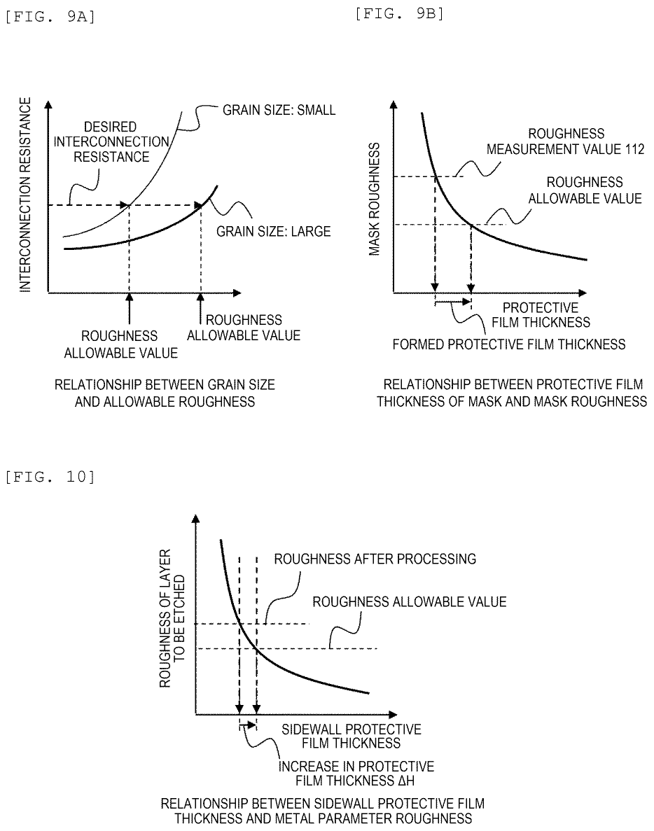

For example, even when the roughness of the mask pattern 103 measured in step S1 is within the allowable value, when the dimension of the pattern of the etching target material (metal film) 102 after processing is smaller than a desired value and the roughness increases, and when the mask roughness after the formation of the sidewall protective film is not within the allowable value, the roughness of the pattern of the etching material (metal film) 102 can be reduced to the allowable value by correcting the condition for the sidewall protective film formation step (step S6). For example, as shown in FIG. 10, if a relationship between the roughness of the pattern of the etching target material (metal film) 102 after processing and the thickness of the formed sidewall protective film or a sidewall protective film formation time is acquired and stored in the storage unit 18, the roughness of the pattern of the etching target material (metal film) 102 after processing can be reduced to be within the allowable value and production of a defective pattern can be avoided by correction under a condition that the thickness of the sidewall protective film is increased by ΔH as a condition for a next wafer processing.

Alternatively, when the dimension of the pattern of the etching target material (metal film) 102 after processing is larger than a desired value whereas the roughness is within the allowable value, the dimension of the pattern etching target material (metal film) 102 after processing can be finely adjusted by shortening a time for the protective film formation (step S3) and the sidewall protective film formation (step S6) and increasing a time for the trimming (step S4).

Next, interconnection resistance is estimated based on the information on the roughness, the dimension, and the grain of the pattern of the etching target material (metal film) 102 obtained in the pattern inspection (step S8) performed after the processing of the etching target material (metal film) 102 (step S10). The information on the dimension, the roughness, and the grain of the pattern of the etching target material (metal film) 102 stored in the storage unit 18 is sent to the calculation unit 19 to estimate the interconnection resistance after processing and calculate a defined value of the roughness. A resistance value of an interconnection can be obtained according to an effective resistance value of the interconnection in consideration of scattering at a sidewall and scattering at a grain boundary as shown in the above (equation 1). The interconnection width d after processing the metal pattern can be obtained from the dimension of the pattern of the etching target material (metal film) 102 in the reflected electron image 121. The sidewall scattering coefficient p varies depending on the roughness of the interconnection, and thus can be obtained from the roughness of the pattern of the etching target material (metal film) 102 measured from the reflected electron image 121. The grain size coefficient D can be obtained from the grain size of the etching target material (metal film) 102 in the reflected electron image 121. After the interconnection resistance is estimated, it is checked whether the resistance value is within the desired resistance value range.

When it is confirmed that the estimated resistance value is within the desired resistance value range, the sidewall protective film 105 and etching residue are removed (step S11). For example, when the sidewall protective film 105, the oxidized etching target material 102, and the etching residue remain in a pattern groove after etching, these are mixed as impurities into the interconnection material and increase the interconnection resistance or cause disconnection, and therefore, it is necessary to remove these impurities after etching.

In this post-processing step (step S11), first, the apparatus control unit 43 controls the gas supply unit 33 to supply the post-processing gas 38 to the processing chamber 31 at predetermined flow rate. In a state in which the post-processing gas 38 is supplied and the inside of the processing chamber 31 reaches predetermined pressure, the apparatus control unit 43 controls the radio frequency power supply 40 to apply the radio frequency power 56 to the radio frequency application unit 41, thereby generating the plasma 42 by the post-processing gas 38 inside the processing chamber 31. The post-processing gas 38 becomes the plasma 42, and generates radicals and ions for removing the sidewall protective film 105, the oxidized film, and the etching residue on the etching target material (metal film) 102. The etching residue can be referred to as an altered layer. As the post-processing gas 38, for example, a mixed gas containing H₂ gas may be used. Alternatively, a mixed gas of H₂ gas and N₂ may be used. Alternatively, the etching residue may be removed by a processing for a short time using a mixed gas containing F.

According to the invention, it is possible to obtain the information on the dimension, the roughness, and the grain of the interconnection pattern under the mask in a non-destructive manner before processing the film to be etched. The interconnection resistance can be estimated based on the measured information on the dimension and the roughness of the mask pattern and on the grain size of the metal film. Further, it is possible to set an optimum etching condition based on the measured information and perform etching such that the roughness of the interconnection pattern is equal to or less than the defined allowable value, thereby enabling etching while ensuring the interconnection resistance and reducing the number of wafers to be discarded. Further, it is possible to estimate the optimum etching condition based on the measured information, create an interconnection pattern with low interconnection resistance, and provide a device with favorable performance.

Although the invention has been specifically described based on the embodiment, the invention is not limited to the embodiment, and it is needless to say that various modifications can be made without departing from the gist of the invention. For example, the above-described embodiment has been described in detail to facilitate understanding of the invention, and the invention is not necessarily limited to those including all the configurations described above. In addition, another configuration can be added to a part of a configuration of each embodiment, and the part of the configuration of each embodiment can be deleted or replaced with another configuration.

### Reference Signs List

1: semiconductor inspection apparatus
2: electronic engineering system
3: stage
4: control unit
5: electron source
7: scanning control unit
8: scanning coil
9: condenser lens
10: objective lens
11: secondary electron detector
12: reflected electron detector
13: amplifier
14: converter
15: detector control unit
16: monitor
17: operation board
18: storage unit
19: calculation unit
20: stage control unit
21: external server
30: plasma processing apparatus
31: processing chamber
32: wafer stage
33: gas supply unit
34: protective film formation gas
35: trimming gas
36: etching gas
37: sidewall protective film formation gas
38: post-processing gas
39: bias power supply
40: radio frequency power supply
41: radio frequency application unit
42: plasma
43: apparatus control unit
44: gas control unit
45: exhaust system control unit
46: radio frequency control unit
47: bias control unit
48: protective film formation step control unit
49: etching control unit
50: database
51: storage unit
52: control unit
53: calculation unit
54: database storage unit
55: bias voltage
56: radio frequency power
57: control signal
100: wafer
101: substrate
102: etching target material (metal film)
103: mask pattern
104: protective film
105: sidewall protective film
111: dimension of mask pattern
112: sidewall roughness of mask pattern
113: dimension of pattern of etching target material (metal film)
114: sidewall roughness of pattern of etching target material (metal film)
115: grain of etching target material (metal film)
116: incident electron beam
117: secondary electron
118: incident electron beam
119: reflected electron
120: secondary electron image
121: reflected electron image

1. A plasma processing method for forming a pattern of a metal film, comprising:
a first step of acquiring, using an image of a mask pattern acquired using an electron beam, information on roughness and a dimension of the mask pattern and on a grain of the metal film;
a third step of defining an etching condition for the metal film based on an allowable value for roughness of the pattern of the metal film; and
a fourth step of etching the metal film using the defined etching condition.

2. The plasma processing method according to claim 1, further comprising:
a second step of obtaining the allowable value for the roughness of the pattern of the metal film corresponding to desired interconnection resistance based on the acquired information on the roughness and the dimension of the mask pattern and on the grain of the metal film.

3. The plasma processing method according to claim 2, wherein
the defined etching condition for the metal film includes a step of forming a protective film on the mask pattern.

4. The plasma processing method according to claim 2, wherein
the defined etching condition for the metal film includes a step of forming a protective film on a sidewall of the metal film.

5. The plasma processing method according to claim 2, wherein
the metal film is made of ruthenium (Ru).

6. The plasma processing method according to claim 1, further comprising:
a second step of estimating a resistance value of an interconnection of the metal film based on the acquired roughness and the acquired dimension of the mask pattern, and a measurement result of a grain size of the metal film.

7. A method for inspecting a pattern of a metal film, comprising:
emitting an electron beam from above a mask pattern for forming the pattern of the metal film to measure roughness and a dimension of the mask pattern, and a grain size of the metal film; and
estimating a resistance value of an interconnection of the metal film based on a result of the measurement.

8. A method for inspecting a pattern of a metal film, comprising:
a first step of acquiring, using an image of a mask pattern acquired using an electron beam, information on roughness and a dimension of the mask pattern and on a grain of the metal film; and
a second step of obtaining an allowable value for roughness of the pattern of the metal film corresponding to desired interconnection resistance based on the acquired information on the roughness and the dimension of the mask pattern and on the grain of the metal film.
